(19) United States
(12) Patent Application Publication
(10) Pub. No.: US 2024/0258986 A1
(43) Pub. Date: Aug. 1, 2024

(54) ACOUSTIC WAVE DEVICE

(71) Applicant: Skyworks Solutions, Inc., Irvine, CA (US)

(72) Inventors: Michael David Hill, Emmitsburg, MD (US); Hiroyuki Nakamura, Osaka-Fu (JP); Takanori Yasuda, Nara-Shi (JP); Rei Goto, Osaka-Shi (JP)

(21) Appl. No.: 18/423,121

(22) Filed: Jan. 25, 2024

Related U.S. Application Data
(60) Provisional application No. 63/441,393, filed on Jan. 26, 2023.

(51) Int. Cl. H03H 9/02; H03H 9/25

(52) U.S. Cl. CPC H03H 9/02834; H03H 9/02559; H03H 9/25

(57) ABSTRACT

An acoustic wave device comprising a piezoelectric substrate with an interdigital transducer electrode disposed on the piezoelectric substrate and configured to excite an acoustic wave having a wavelength of λ. The device includes a temperature compensating layer disposed on the interdigital transducer electrode and having a dielectric material including a titanium compound.

### INCORPORATION BY REFERENCE TO ANY PRIORITY APPLICATIONS

Any and all application for which a foreign or domestic priority claim identified in the Application Data Sheet as filed with the present application are hereby incorporated by reference under 37 CFR 1.57.

### BACKGROUND

### Field

Embodiments of the invention relate to acoustic wave devices and/or radio frequency (RF) modules.

### Description of the Related Technology

An acoustic wave filter can include a plurality of resonators arranged to filter a radio frequency signal. Example acoustic wave resonators include surface acoustic wave (SAW) resonators and bulk acoustic wave (BAW) resonators. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed. A multi-mode SAW filter can include a plurality of longitudinally coupled interdigital transducer electrodes positioned between acoustic reflectors. In BAW resonators, acoustic waves propagate in a bulk of a piezoelectric layer. Example BAW resonators include film bulk acoustic wave resonators (FBARs) and solidly mounted resonators (SMRs).

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, three acoustic wave filters can be arranged as a triplexer. As another example, four acoustic wave filters can be arranged as a quadplexer.

Acoustic wave filters with small package size are generally desirable. However, decreasing the size of an acoustic wave filter can be challenging.

### SUMMARY

The innovations described in the claims each have several aspects, no single one of which is solely responsible for its desirable attributes. Without limiting the scope of the claims, some prominent features of this disclosure will now be briefly described.

In a first aspect, an acoustic wave device is disclosed. The acoustic wave device includes a piezoelectric substrate and an interdigital transducer (IDT) electrode. The interdigital transducer electrode is disposed on the piezoelectric substrate and configured to excite an acoustic wave having a wavelength of 2. The acoustic wave device also includes a temperature compensating layer disposed on the interdigital transducer electrode. The temperature compensating layer has a dielectric material including a titanium compound.

The titanium compound can be titanium dioxide (TiO₂). The dielectric material can have a weight proportion of the titanium compound in a range from about 0.1 mass-% to about 10 mass-%. In particular, the weight proportion of the titanium compound can be in a range from about 3 mass-% to about 7 mass-%. The weight proportion of the titanium compound can also be about 5 mass-%. The weight proportion of the titanium compound can be in a range from 0.1 mass-% to 10 mass-%. In particular, the weight proportion of the titanium compound can be in a range from 3 mass-% to 7 mass-%. The weight proportion of the titanium compound can also be 5 mass-%.

The dielectric material can comprise a silicon compound. The silicon compound can be silicon dioxide (SiO₂). The dielectric material can have a weight proportion of the silicon compound in a range from about 90 mass-% to about 99.9 mass-%. In particular, the weight proportion of the silicon compound can be in a range from about 93 mass-% to about 97 mass-%. The weight proportion of the silicon compound can also be about 95 mass-%. The dielectric material can have a weight proportion of the silicon compound in a range from 90 mass-% to 99.9 mass-%. In particular, the weight proportion of the silicon compound can be in a range from 93 mass-% to 97 mass-%. The weight proportion of the silicon compound can also be 95 mass-%.

The dielectric material can be composed such that the acoustic wave device has a temperature coefficient of resonant frequency (TCFs) of at least −32.4 ppm/K. In particular, the dielectric material can be composed such that the acoustic wave device has a temperature coefficient of resonant frequency (TCFs) of at least −30.9 ppm/K.

The dielectric material can be composed such that the acoustic wave device has a temperature coefficient of anti-resonant frequency (TCFp) of at least −19.2 ppm/K. In particular, the dielectric material can be composed such that the acoustic wave device has a temperature coefficient of anti-resonant frequency (TCFp) of at least −17.5 ppm/K.

The piezoelectric substrate can include lithium tantalate (LiTaO₃). Alternatively or additionally, the piezoelectric substrate can include lithium niobate (LiNbO₃).

The acoustic wave device can be configured as a surface acoustic wave (SAW) device.

In a second aspect, a radio frequency module is disclosed. The radio frequency module includes an acoustic wave filter. The acoustic wave filter includes an acoustic wave device and is configured to filter a radio frequency signal. The acoustic wave device has a piezoelectric substrate and an interdigital transducer electrode. The interdigital transducer electrode is disposed on the piezoelectric substrate and configured to excite an acoustic wave having a wavelength of 2. The acoustic wave device also has a temperature compensating layer disposed on the interdigital transducer electrode. The temperature compensating layer comprises a dielectric material. The dielectric material includes a titanium compound. The radio frequency module further includes a radio frequency circuit element coupled to the acoustic wave filter. The acoustic wave filter and the radio frequency circuit element being enclosed within a common module package.

The radio frequency module can be configured as a front end module.

The acoustic wave device can be configured as a SAW device. The SAW device can be configured as a temperature compensated surface acoustic wave (TCSAW) device.

The filter architecture of the acoustic wave filter can be of a Double Mode SAW (DMS) type, a ladder type, a lattice type or a hybrid ladder and lattice type.

The radio frequency circuit element can be a radio frequency amplifier arranged to amplify a radio frequency signal.

The radio frequency circuit element can be a switch configured to selectively couple the acoustic wave filter to a port of the radio frequency module.

In a third aspect, a wireless communication device is disclosed. The wireless communication device includes an acoustic wave filter. The acoustic wave filter includes an acoustic wave device and is configured to filter a radio frequency signal. The acoustic wave device has a piezoelectric substrate and an interdigital transducer electrode. The interdigital transducer electrode is disposed on the piezoelectric substrate and configured to excite an acoustic wave having a wavelength of λ. The acoustic wave device also has a temperature compensating layer disposed on the interdigital transducer electrode. The temperature compensating layer comprises a dielectric material. The dielectric material includes a titanium compound. The wireless communication device further includes an antenna operatively coupled to the acoustic wave filter. The wireless communication device further includes a radio frequency amplifier operatively coupled to the acoustic wave filter and configured to amplify the radio frequency signal. The wireless communication device further includes a transceiver in communication with the radio frequency amplifier.

The wireless communication device can further include a baseband processor in communication with the transceiver.

The acoustic wave filter can be included in a radio frequency front end.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A is a simplified plan view of an example of a surface acoustic wave resonator.

FIG. 1B is a simplified plan view of another example of a surface acoustic wave resonator.

FIG. 1C is a simplified plan view of another example of a surface acoustic wave resonator.

FIG. 2A is a cross-sectional view of a portion of a baseline surface acoustic wave device.

FIG. 2B is a cross-sectional view of a portion of a surface acoustic wave device that includes a dielectric material comprising a titanium compound according to an embodiment.

FIG. 3A is a graph showing simulated frequency responses of the baseline surface acoustic wave device of FIG. 2A at two different temperatures.

FIG. 3B is a graph showing simulated frequency responses of the surface acoustic wave device of FIG. 2B at two different temperatures.

FIG. 4 is a graph comparing simulated frequency responses of the surface acoustic wave devices of FIGS. 2A and 2B for several oxide glasses.

FIG. 5A is a schematic block diagram of a module with a filter that includes a surface acoustic wave device according to an embodiment.

FIG. 5B is a schematic block diagram of a module with a filter that includes a surface acoustic wave device according to another embodiment.

FIG. 5C is a schematic block diagram of a module with a filter that includes a surface acoustic wave device according to another embodiment.

FIG. 6A is a schematic block diagram of a module with duplexers that include a surface acoustic wave device according to an embodiment.

FIG. 6B is a schematic block diagram of a module with duplexers that include a surface acoustic wave device according to another embodiment.

FIG. 6C is a schematic block diagram of a module with duplexers that include a surface acoustic wave device according to another embodiment.

FIG. 7 is a schematic block diagram of a wireless communication device that includes filters in accordance with one or more embodiments.

FIG. 8 is a schematic diagram of a ladder filter according to another embodiment.

FIG. 9 is a schematic diagram of a lattice filter.

FIG. 10 is a schematic diagram of a hybrid ladder and lattice filter.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. A SAW device can be, for example, a multimode longitudinally coupled SAW filter (e.g., a double mode SAW (DMS) filter) or a SAW resonator.

Multimode SAW (MMS) filters can be useful for meeting certain design specifications for radio frequency (RF) filter components. In order for an MMS filter to provide a desired frequency response for some design specifications, a pitch of an interdigital transducer (IDT) electrode structure can be modulated such that fingers of the IDT structure are unevenly spaced. However, in some applications, such an MMS filter with varying and/or uneven IDT electrode pitch can lead to radiation losses, for example, due to discontinuity and/or process limitations for relatively high frequency filter devices. The loss mechanism due to aperiodicity of IDT electrode fingers can be difficult to quantify and/or model. Further, there may be manufacturing difficulties for manufacturing a SAW device with varying/uneven pitch. There may be manufacturing limitations to forming narrow pitch IDT electrode fingers in certain manufacturing processes.

Aspects of this disclosure relate to SAW devices (e.g., multimode longitudinally coupled SAW filters and/or SAW resonators) that can reduce and/or eliminate radiation losses. At the same time, such SAW devices can provide a desirable frequency response (e.g., a relatively high quality factor (Q) and/or a reduced bulk radiation). Aspects of this disclosure relate to SAW devices that include first and second acoustic wave filter components which are electrically coupled to a shared node/electrically conductive path.

Embodiments of a SAW filter disclosed herein include a first IDT electrode, a second IDT electrode longitudinally coupled to the first IDT electrode, and an acoustic reflector that are on a piezoelectric layer. The SAW filter can also include an acoustic velocity adjustment structure over at least a gap between the first IDT electrode and the second IDT electrode. This can increase acoustic velocity in a region over the gap. The acoustic velocity adjustment structure can be arranged to change acoustic wave propagation velocity in different regions. The acoustic velocity adjustment structure can include a high speed layer and/or a trench in a low speed layer to increase acoustic velocity in a region of the SAW filter. The acoustic velocity adjustment structure can include a low speed layer and/or a trench in a high speed layer to increase acoustic velocity in a region of the SAW filter. Different acoustic velocity regions can alternatively or additionally be implemented by high speed layers that increase acoustic velocity by different magnitudes and/or low speed layers that decrease acoustic velocity by different magnitudes. The acoustic velocity adjustment structure can be included in a vertical stack that is arranged over the piezoelectric layer and one or more of the IDT electrodes.

Certain embodiments disclosed herein relate to multimode longitudinally coupled surface acoustic wave filters. Such filters can be referred to as multimode surface acoustic wave (MNMS) filters. MMS filters can include a plurality of IDT electrodes that are longitudinally coupled to each other and positioned between acoustic reflectors. Some MMS filters can be referred to as double mode surface acoustic wave (DMS) filters. There may be more than two modes of such DMS filters and/or for other MMS filters.

MNMS filters can have a relatively wide passband due to a combination of various resonant modes. MMS filters can have a balanced (differential) input and/or a balanced output with proper arrangement of IDTs. MNMS filters can achieve a relatively low loss and a relatively good out of band rejection.

MNMS filters can be temperature compensated by including a temperature compensation layer, such as a silicon dioxide (SiO₂) layer, over IDT electrodes. Such a temperature compensation layer can cause a temperature coefficient of frequency (TCF) of an MMS filter to be closer to zero. In some applications, an MNMS filter can include a multi-layer piezoelectric substrate.

In certain applications, MNMS filters can be receive filters arranged to filter radio frequency signals received by an antenna. MMS filters can be included in a receive filter that also includes a plurality of acoustic resonators arranged in a ladder topology.

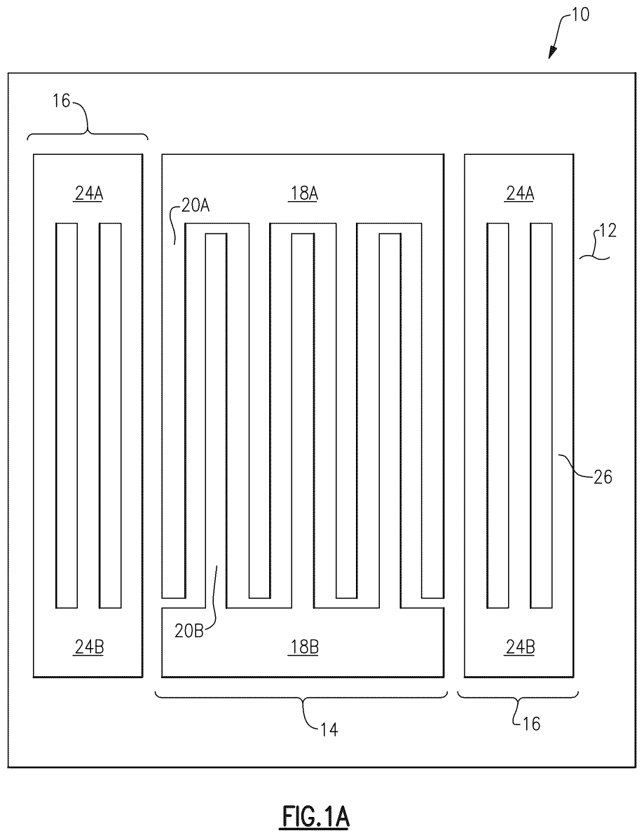

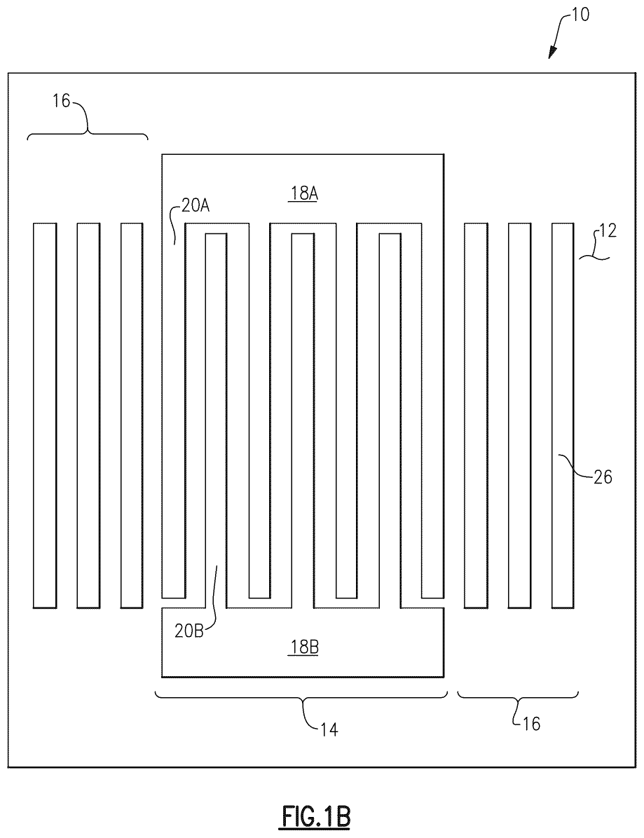

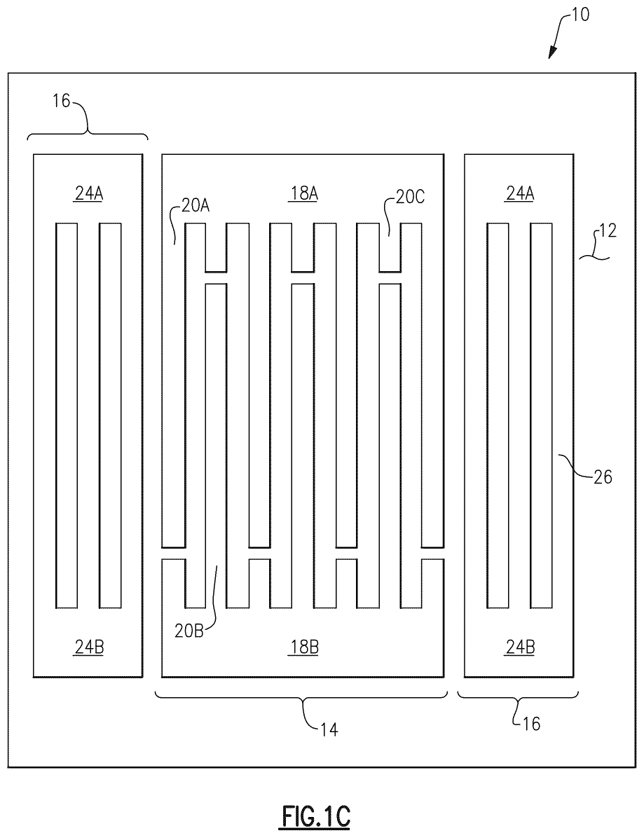

FIG. 1A is a plan view of a surface acoustic wave (SAW) device 10 such as might be used in a SAW filter, duplexer, diplexer, balun, etc.

The surface acoustic wave resonant device or 10 is formed on a piezoelectric substrate, for example, a lithium tantalate (LiTaO₃) or lithium niobate (LiNbO₃) substrate 12 and includes Interdigital Transducer (IDT) electrodes 14 and reflector electrodes 16. In use, the IDT electrodes 14 excite a main acoustic wave having a wavelength λ along a surface of the piezoelectric substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18 B facing first bus bar electrode 18A. The bus bar electrodes 18A, 18B may be referred to herein and labelled in the figures as busbar electrode 18. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B (collectively referred to herein as reflector bus bar electrode 24) and reflector fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector fingers 26 may be electrically unconnected. Further, as illustrated in FIG. 1C, acoustic wave resonators as disclosed herein may include dummy electrode fingers 20C that are aligned with respective electrode fingers 2A, 20 B. Each dummy electrode finger 20C extends from the opposite bus bar electrode 18A, 18B than the respective electrode finger 20A, 20B with which it is aligned.

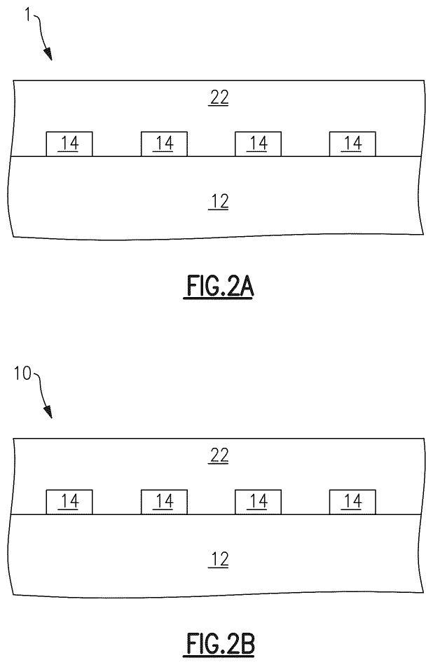

FIG. 2A illustrates a cross section of a baseline surface acoustic wave device 1. The baseline surface acoustic device 1 includes a piezoelectric substrate 12, IDT electrodes 14 on the piezoelectric substrate 12, and a temperature compensating layer 22 disposed on the interdigital transducer electrodes 14. The illustrated IDT electrodes 14 are aluminum IDT electrodes. The IDT electrodes 14 have a pitch that sets a wavelength λ or L of a surface acoustic wave generated by the surface acoustic wave device 1. The temperature compensating layer 22 is made of silicon dioxide (SiO₂). The piezoelectric substrate 12 and the IDT electrodes 14 are bonded with each other and in physical contact with each other in the surface acoustic wave device 1. Furthermore, the piezoelectric substrate 12 and the temperature compensating layer 22 are bonded with each other and in physical contact with each other in the surface acoustic wave device 1.

FIG. 2B illustrates a cross section of a surface acoustic wave device 10 that includes a dielectric material 22 comprising a titanium compound according to an embodiment. The surface acoustic wave device 10 includes a piezoelectric substrate 12, IDT electrodes 14 on the piezoelectric substrate 12, and a temperature compensating layer 22 disposed on the interdigital transducer electrodes 14. The interdigital transducer electrodes 14 and the temperature compensating layer 22 form a surface acoustic wave resonator, for instance like illustrated in FIGS. 1A-1C. The surface acoustic wave device 10 is like the surface acoustic wave device 1 of FIG. 2A except that the surface acoustic wave device 10 includes the dielectric material 22 comprising a titanium compound in place of the pure silicon dioxide.

For example, the IDT electrodes 14 are disposed on the piezoelectric substrate 12. The IDT electrodes 14 are formed of a metal or metal alloy, for example, aluminum. Optionally, the IDT electrodes 14 may include multiple layers of different metals, for example, molybdenum and aluminum.

The dielectric material 22, for example, a silicon dioxide (SiO₂)-titanium dioxide (TiO₂) compound may be disposed on top of the IDT electrodes 14 and the piezoelectric substrate 12. This can contribute to the surface acoustic wave device 10 achieving a desired electromechanical coupling coefficient λ. The dielectric material may advantageously decrease the effect of changes in temperature upon operating characteristics of the acoustic wave device 10 and may protect the IDT electrodes 14 and surface of the piezoelectric substrate 12. For example, SiO₂—TiO₂ has a negative coefficient of thermal expansion while materials typically used for the piezoelectric substrate 12 in a SAW device have a positive coefficient of thermal expansion. The temperature compensating layer of SiO₂—TiO₂ 22 may thus oppose changes in dimensions of piezoelectric substrate 12 with changes in temperature that might otherwise occur in the absence of the temperature compensating layer of SiO₂—TiO₂ 22. SAW devices including a layer of SiO₂—TiO₂ as illustrated in FIG. 2B may be referred to as temperature-compensated SAW devices, often abbreviated as TCSAW devices. That means, the temperature compensating layer 22 can be configured to reduce a temperature-dependent drift of the filter frequency.

For example, the piezoelectric substrate 12 can include lithium tantalate (LiTaO₃), lithium niobate (LiNbO₃) or similar compositions. Alternatively or additionally, the piezoelectric substrate 12 can include a lithium tantalate layer being an example of a piezoelectric layer. A lithium niobate (LiNbO₃) piezoelectric layer can be implemented in place of a lithium tantalate layer in any of the embodiments discussed herein. Any other suitable piezoelectric substrate 12 or piezoelectric layer can be implemented in place of the lithium tantalate layer.

The IDT electrodes 14 are disposed on piezoelectric substrate 12. The IDT electrodes 14 have a pitch that sets the wavelength λ of a surface acoustic wave generated by the surface acoustic wave device 10. The IDT electrodes 14 can be an aluminum IDT electrode. IDT electrode material can include aluminum (Al), titanium (Ti), gold (Au), silver (Ag), copper (Cu), platinum (Pt), tungsten (W), molybdenum (Mo), ruthenium (Ru), or any suitable combination thereof. For instance, the IDT electrodes 14 can include aluminum and molybdenum in certain applications. In some embodiments, the IDT electrodes 14 can include multiple layers of different IDT electrode materials.

It should be appreciated that the acoustic wave resonators and acoustic wave devices illustrated in FIGS. 1A-2B, as well as those illustrated in other figures presented herein, are illustrated in a highly simplified form. The relative dimensions of the different features are not shown to scale. Further, typical acoustic wave resonators would commonly include a far greater number of electrode fingers and/or reflector fingers than illustrated. The acoustic wave resonators may be configured differently than illustrated in some examples, for example, to include dummy electrode fingers, electrode fingers with different or non-uniform length or width dimensions, electrode fingers or reflector fingers with different or non-uniform spacing, or electrode fingers that include bent or tilted portions. Typical acoustic wave resonators or filter elements may also include multiple IDT electrodes sandwiched between the reflector electrodes.

As technology advances, consumers and manufacturers continue to demand additional functionality in a smaller footprint in electronic devices, for example, cellular telephones or other radio frequency devices that may utilize SAW devices as disclosed herein. One method of reducing the footprint of one or more SAW devices or acoustic filters is to use a stacked structure in which multiple substrates and associated devices are stacked one on another. The stacked structure may include more devices per unit area than the individual substrates would if not stacked.

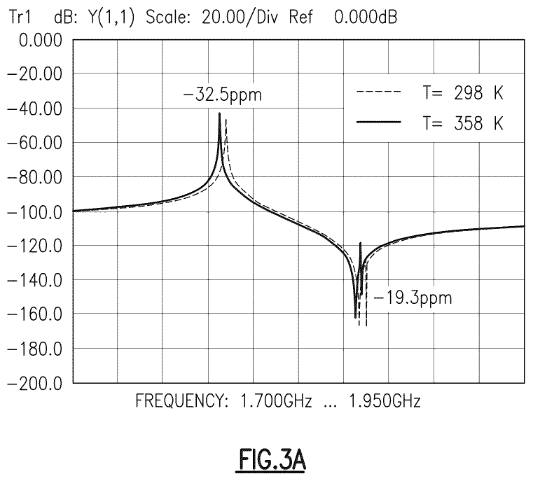

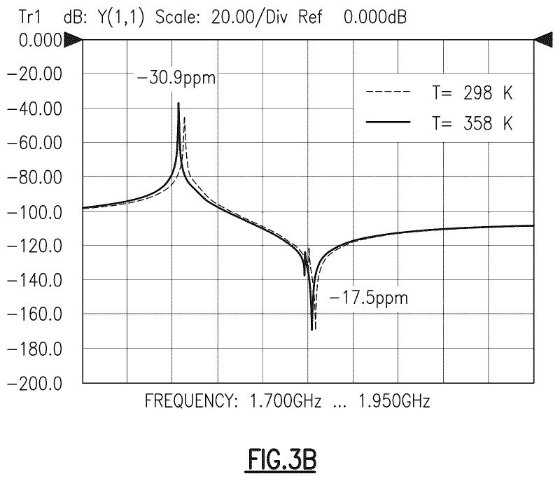

FIG. 3A is a graph showing simulated frequency responses of the baseline surface acoustic wave device 1 of FIG. 2A at two different temperatures. The first of two different temperatures is 298 K corresponding to 25° C. The second of two different temperatures is 358 K corresponding to 85° C. These simulations correspond to a wavelength λ or L of 2 μm, a temperature compensating layer 22 having a thickness of 560 nm, a first layer of the IDT electrode 14 having a thickness of 160 nm and being an aluminum layer, and a second layer of the IDT electrode 14 having a thickness of 80 nm and being a molybdenum layer. These simulations are carried out with a CAE software based on finite element methods (FEM).

The baseline surface acoustic wave device 1 has a temperature coefficient of resonant frequency (TCFs) of −32.5 ppm/K. The baseline surface acoustic wave device 1 has a temperature coefficient of anti-resonant frequency (TCFp) of −19.3 ppm/K. For achieving a desirable electromechanical coupling coefficient k2 value, the simulation results indicate that there is a trade off between TCF and k2. For instance, a thicker SiO₂ layer results in a better TCF, but k2 is decreased. The closer TCF is to zero the better the TCF is, while a higher k2 is generally desirable.

FIG. 3B is another graph showing simulated frequency responses of the surface acoustic wave device 10 of FIG. 2B at two different temperatures. The first of two different temperatures is 298 K corresponding to 25° C. The second of two different temperatures is 358 K corresponding to 85° C. These simulations correspond to a wavelength λ or L of 2 μm, a temperature compensating layer 22 having a thickness of 560 nm, a first layer of the IDT electrode 14 having a thickness of 160 nm and being an aluminum layer, and a second layer of the IDT electrode 14 having a thickness of 80 nm and being a molybdenum layer. These simulations are carried out with a CAE software based on finite element methods (FEM).

This graph indicates a lower temperature coefficient of resonant frequency (TCF) in the surface acoustic wave device 10 than in the baseline surface acoustic wave device 1. The surface acoustic wave device 10 has a temperature coefficient of resonant frequency (TCFs) of −30.9 ppm/K. The surface acoustic wave device 1 has a temperature coefficient of anti-resonant frequency (TCFp) of −17.5 ppm/K.

The temperature compensating layer 22 can be a SiO₂—TiO₂ layer. This can bring the TCF of such a surface acoustic wave device 10 closer to zero than the baseline surface acoustic wave device 1 of FIG. 2A. Accordingly, there can be less variation with temperature for the surface acoustic wave device 10 with the temperature compensating layer 22. This can be significant in certain applications.

For example, the dielectric material can have a weight proportion of the SiO₂ of about 95 mass-%. Furthermore, the dielectric material can have a weight proportion of the TiO₂ of about 5 mass-%, for instance. The sum of both weight proportions is 100 mass-%. Hence, the surface acoustic wave device 10 comprising the dielectric material being SiO₂—TiO₂ can improve the TCF by about 1.6-1.8 ppm/K without any penalty of k2. A temperature compensating layer 22 can include any suitable combination of SiO₂ and TiO₂.

For example, the dielectric material can have a weight proportion of the SiO₂ of 95 mass-%. Furthermore, the dielectric material can have a weight proportion of the TiO₂ of 5 mass-%, for instance. The sum of both weight proportions is 100 mass-%. Hence, the surface acoustic wave device 10 comprising the dielectric material being SiO₂—TiO₂ can improve the TCF by 1.6-1.8 ppm/K without any penalty of k2. A temperature compensating layer 22 can include any suitable combination of SiO₂ and TiO₂.

In the simulations of FIGS. 3A and 3B, the material properties in Table 1 were used and achieved, respectively.

TABLE 1

| | | Young M. | Poisson R. | | | | TCDs | TCDp | TCFs | TCFp |
|---|---|---|---|---|---|---|---|---|---|---|
| | T[deg] | [10¹¹ Pa] | [—] | fs[GHz] | fp[GHz] | K2[%] | [ppm/K] | [ppm/K] | [ppm/K] | [ppm/K] |
| SiO₂ | 25 | 0.6400 | 0.1300 | 1.7848 | 1.8584 | 9.40% | −16.8 | −3.6 | −32.5 | −19.3 |
| | 85 | 0.6472 | 0.1324 | 1.783 | 1.858 | 9.57% | | | | |
| SiO₂- | 25 | 0.5760 | 0.1300 | 1.7564 | 1.829 | 9.42% | −15.2 | −1.8 | −30.9 | −17.5 |
| TiO₂ | 85 | 0.5829 | 0.1324 | 1.7548 | 1.8288 | 9.59% | | | | |

For the TCF a Young module TCF was assumed. A line expansion TCF has not been included in the simulation. The SiO₂—TiO₂ Young module was assumed to be 90% of the one of the conventional SiO₂.

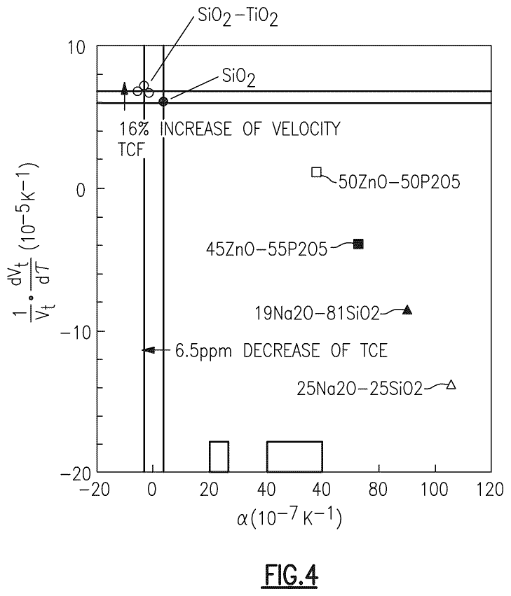

FIG. 4 is a graph comparing simulated frequency responses of the surface acoustic wave devices 1, 10 of FIGS. 2A and 2B for several oxide glasses. The graph illustrates a relationship between a temperature coefficient of transverse sound velocity (1/Vt)(dVt/dT) at 273 K and a thermal expansion coefficient α at 273 K. The several oxide glasses are SiO₂, SiO₂—TiO₂, 50ZnO-50P₂O₅, 45ZnO-55P₂O₅, 19Na₂O-81SiO₂ and 25Na₂O-75SiO₂, for example. The SiO₂ oxide glass can correspond to the baseline surface acoustic wave device 1. The SiO₂—TiO₂ oxide glass can correspond to the surface acoustic wave device 10, in particular to the surface acoustic wave device 10 of FIGS. 2B and 3B.

This graph indicates a higher temperature coefficient of transverse sound velocity, also called velocity TCF, in the surface acoustic wave device 10 than in the baseline surface acoustic wave device 1. In particular, the velocity TCF is about 16% higher. Further, this graph indicates a lower thermal expansion coefficient, also called TCE, in the surface acoustic wave device 10 than in the baseline surface acoustic wave device 1. In particular, the TCE is about 6.5 ppm/K lower.

The acoustic wave devices disclosed herein can be implemented in acoustic wave filters arranged to filter radio frequency signals. Aspects of this disclosure relate to filtering a radio frequency signal with an acoustic wave filter. A method can include providing a radio frequency signal to an acoustic wave filter. The radio frequency signal can provided via a radio frequency switch, for example. In some instances, a power amplifier can provide the radio frequency signal to the acoustic wave filter via the radio frequency switch. The method includes filtering the radio frequency signal with the acoustic wave filter. The acoustic wave filter can include any suitable acoustic wave device disclosed herein. For example, the acoustic wave filter can include an acoustic wave device includes a piezoelectric substrate, IDT electrodes on the piezoelectric substrate, and a temperature compensating layer disposed on the interdigital transducer electrodes. The piezoelectric substrate can have a thickness that is less than 2, in which the acoustic wave device is configured to generate an acoustic wave having a wavelength of 2. The acoustic wave device can include a temperature compensating layer, such as a silicon dioxide-titanium dioxide (SiO₂—TiO₂) layer, disposed on the piezoelectric substrate and the IDT electrodes. In the method, the radio frequency signal can be filtered while higher-order modes are suppressed.

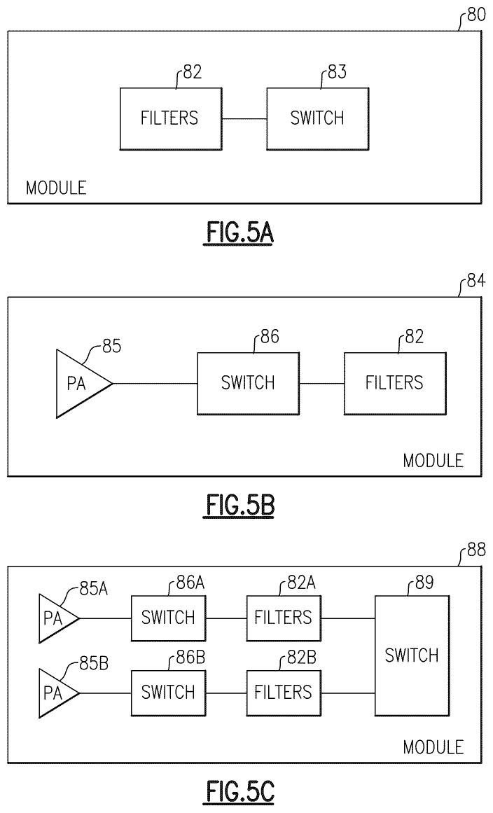

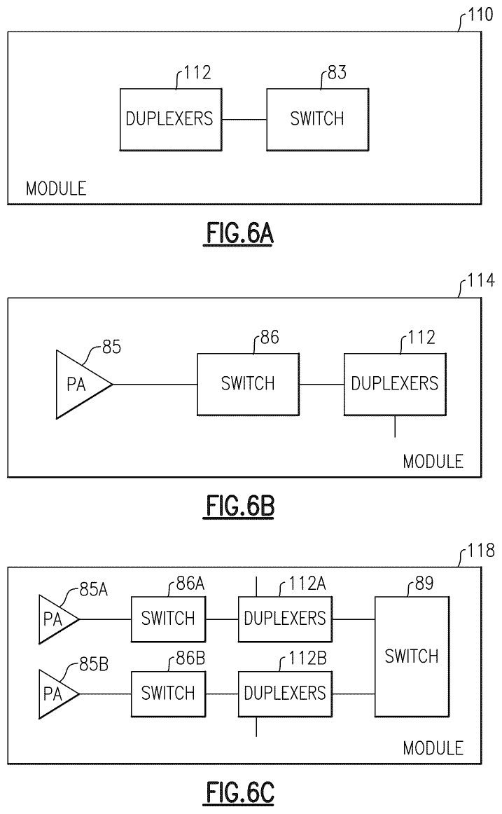

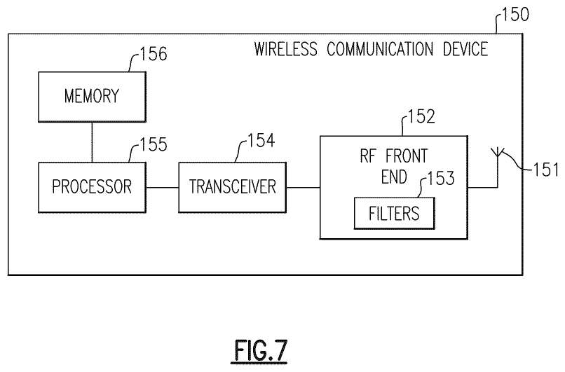

The acoustic wave devices discussed herein can be implemented in a variety of packaged modules. A packaged module configured to process a radio frequency signal can be referred to as a radio frequency module. Some example packaged modules will now be discussed in which any suitable principles and advantages of the acoustic wave devices discussed herein can be implemented. FIGS. 5A to 6C are schematic block diagrams of illustrative packaged modules according to certain embodiments. Any suitable combination of features of these embodiments can be combined with each other. FIGS. 5A to 5C illustrate modules that include filters that includes an acoustic device in accordance with the principles and advantages disclosed herein. FIGS. 6A to 6C illustrate modules that include duplexers that includes an acoustic device in accordance with the principles and advantages disclosed herein. Although FIGS. 6A to 6C illustrate duplexers, any suitable principles and advantages disclosed herein can be implemented in other multiplexers (e.g., quadplexers, hexaplexers, octoplexers, etc.) and/or in switch-plexers.

FIG. 5A is a schematic block diagram of a module 80 that includes filters 82 and a switch 83. The module 80 can include a package that encloses the illustrated elements. The filters 82 and the switch 83 can be disposed on a common packaging substrate. The packaging substrate can be a laminate substrate, for example. The switch 83 can be a multi-throw radio frequency switch. The switch 83 can electrically couple a selected filter of the filters 82 to a common node. The common node can be an antenna node, for example. As another example, the common node can be coupled to an output of a power amplifier. The filters 82 can include any suitable number of acoustic wave filters. One or more of the acoustic wave filters of the filters 82 can be implemented in accordance with any suitable principles and advantages of the acoustic wave devices discussed herein.

FIG. 5B is a schematic block diagram of a module 84 that includes a power amplifier 85, a switch 86, and filters 82 in accordance with one or more embodiments. The module 84 can include a package that encloses the illustrated elements. The power amplifier 85, the switch 86, and the filters 82 can be disposed on a common packaging substrate. The packaging substrate can be a laminate substrate, for example. The switch 86 can be a multi-throw radio frequency switch. The switch 86 can electrically couple an output of the power amplifier 85 to a selected filter of the filters 82. The filters 82 can include any suitable number of acoustic wave filters. One or more of the acoustic wave filters of the filters 82 can be implemented in accordance with any suitable principles and advantages of the acoustic wave devices discussed herein.

FIG. 5C is a schematic block diagram of a module 88 that includes power amplifiers 85 A and 85 B, switches 86 A and 86 B, and filters 82 A and 82 B, and switch 89. The module 88 can include a package that encloses the illustrated elements. The illustrated elements can be disposed on a common packaging substrate. The packaging substrate can be a laminate substrate, for example. The module 88 is like the module 84 of FIG. 5B, except that the module 88 includes an additional power amplifier 85 B, an additional switch 86 B, additional filters 82 B, and an antenna switch 89. The antenna switch 89 can selectively couple a signal from the filters 82 A or the filters 82 B to an antenna node. The different signal paths can be associated with different frequency bands and/or different modes of operation (e.g., different power modes, different signaling modes, etc.).

Some or all the filters 82 of the modules 80, 84 of FIGS. 5A-5B and/or some or all the filters 82A, 82B of the module 88 of FIG. 5C can include a plurality of surface acoustic wave resonator devices (e.g., any of the devices 1, 10 of FIGS. 1A-1C and 2A-2B) arranged with respect to one another to form a filter.

FIG. 6A is a schematic block diagram of a module 110 that includes duplexers 112 and a switch 83. The module 110 can include a package that encloses the illustrated elements. The duplexers 112 and the switch 83 can be disposed on a common packaging substrate. The packaging substrate can be a laminate substrate, for example. The duplexers 112 can include two or more filters coupled to a common node. The switch 83 can electrically couple a selected duplexer of the duplexers 112 to a common node. The common node can be an antenna node, for example. As another example, the common node can be coupled to an output of a power amplifier.

One or more duplexers of the duplexers 112 can be implemented by any other suitable multiplexer that includes a plurality of filters coupled to each other at a common node. In some embodiments, such a multiplexer can be a quadplexer. The multiplexer can be a pentaplexer. The multiplexer can be a hexaplexer. The multiplexer can be a heptaplexer. The multiplexer can be an octoplexer.

FIG. 6B is a schematic block diagram of a module 114 that includes a power amplifier 85, a switch 86, and duplexers 112 in accordance with one or more embodiments. The module 114 can include a package that encloses the illustrated elements. The power amplifier 85, the switch 86, and the duplexers 112 can be disposed on a common packaging substrate. The packaging substrate can be a laminate substrate, for example. The switch 86 can be a multi-throw radio frequency switch. The switch 86 can electrically couple an output of the power amplifier 85 to a selected duplexer of the duplexers 112. The duplexers 112 can each include two acoustic wave filters coupled to a common node. The two acoustic wave filters can be a transmit filter and a receive filter.

FIG. 6C is a schematic block diagram of a module 118 that includes power amplifiers 85 A and 85 B, switches 86 A and 86 B, and duplexers 112 A and 112 B, and switch 89. The module 118 can include a package that encloses the illustrated elements. The illustrated elements can be disposed on a common packaging substrate. The packaging substrate can be a laminate substrate, for example. The module 118 is like the module 114 of FIG. 6B, except that the module 118 includes an additional power amplifier 85 B, an additional switch 86 B, additional duplexers 112 B, and an antenna switch 89. The antenna switch 89 can selectively couple a signal from the duplexers 112 A or the duplexers 112 B to an antenna node. The different signal paths can be associated with different frequency bands and/or different modes of operation (e.g., different power modes, different signaling modes, etc.).

Some or all the duplexers 112 of the modules 110, 114 of FIGS. 6A-6B and/or some or all the duplexers 112A, 112B of the module 118 of FIG. 6C can include a plurality of surface acoustic wave resonator devices (e.g., any of the devices 1, 10 of FIGS. 1A-1C and 2A-2B) arranged with respect to one another to form a filter.

FIG. 7 is a schematic block diagram of a wireless communication device 150 that includes filters 153 in accordance with one or more embodiments. The wireless communication device 150 can be any suitable wireless communication device. For instance, a wireless communication device 150 can be a mobile phone, such as a smart phone. As illustrated, the wireless communication device 150 includes an antenna 151, an RF front end 152, an RF transceiver 154, a processor 155, and a memory 156. The antenna 151 can transmit RF signals provided by the RF front end 152. The antenna 151 can provide received RF signals to the RF front end 152 for processing.

RF front end 152 can include one or more power amplifiers, one or more low noise amplifiers, RF switches, receive filters, transmit filters, duplexer or other multiplexers, or any combination thereof. The RF front end 152 can transmit and receive RF signals associated with any suitable communication standards. Any of the acoustic wave filters, duplexers, and/or multiplexers discussed herein can be implemented by the filters 153 of the RF front end 152.

The RF transceiver 154 can provide RF signals to the RF front end 152 for amplification and/or other processing. The RF transceiver 154 can also process an RF signal provided by a low noise amplifier of the RF front end 152. The RF transceiver 154 is in communication with the processor 155. The processor 155 can be a baseband processor. The processor 155 can provide any suitable base band processing functions for the wireless communication device 150. The memory 156 can be accessed by the processor 155. The memory 156 can store any suitable data for the wireless communication device 150.

Some or all the filters 153 of the RF front end 152 of FIG. 7 can include a plurality of surface acoustic wave resonator devices (e.g., any of the devices 1, 10 of FIGS. 1A-1C and 2A-2B) arranged with respect to one another to form a filter.

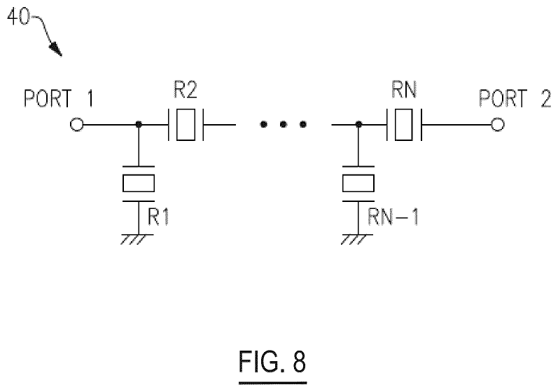

FIG. 8 is a schematic diagram of a ladder filter 40 according to an embodiment. The ladder filter 40 includes a plurality of acoustic resonators R1, R2, . . . , RN−1, and RN arranged between a first input/output port PORT 1 and a second input/output port PORT 2. One of the input/output ports PORT 1 or PORT 2 can be an antenna port. In certain instances, the other of the input/output ports PORT 1 or PORT 2 can be a receive port. In some other instances, the other of the input/output ports PORT 1 or PORT 2 can be a transmit port.

The ladder filter 40 illustrates that any suable number of ladder stages can be implemented in a ladder filter. Ladder stages can start with a series resonator or a shunt resonator from any input/output port of the ladder filter 40 as suitable. As illustrated, the first ladder stage from the input/output port PORT 1 can begin with a shunt resonator R1. As also illustrated, the first ladder stage from the input/output port PORT 2 can begin with a series resonator RN.

The ladder filter 40 includes shunt resonators R1 and RN−1 and series resonator R2 and RN. The series resonators of the ladder filter 40 including resonators R2 and RN can be acoustic resonators of a first type that have higher Q than series resonators of a second type in a frequency range below fs. The shunt resonators of the ladder filter 40 including resonators R1 and RN−1 can be acoustic resonators of the second type and have higher Q than shunt resonators of the first type in a frequency range between fs and fp. This can lead to a reduced insertion loss. The ladder filter 40 can be a band pass filter with series resonators of the first type and shunt resonators of the second type. In some other embodiments, the series resonators of the ladder filter 40 including resonators R2 and RN can be acoustic resonators of the second type and the shunt resonators of the ladder filter 40 including resonators R1 and RN−1 can be acoustic resonators of the first type. In such embodiments, the ladder filter 40 can be a band pass filter.

In some embodiments, the resonators of the first type can be TCSAW resonators such as any of the resonators described herein (e.g., the devices 1, 10 of FIGS. 1A-1C or FIG. 2A-2B) and the resonators of the second type can be BAW resonators or non-temperature compensated SAW devices. Accordingly, the ladder filter 40 can include series TCSAW resonators and shunt BAW resonators in certain embodiments. Such BAW resonators can include FBARs and/or solidly mounted resonators (SMRs). In other embodiments, there are not two types of resonators, and instead both the series and shunt resonators are all TCSAW resonators, which can be any of the devices described herein (e.g., the devices 1, 10 of FIGS. 1A-1C or FIG. 2A-2B).

In a band pass filter with a ladder filter topology, such as the acoustic wave filter 40, the shunt resonators can have lower resonant frequencies than the series resonators. In certain embodiments, the shunt resonators of the acoustic wave filter 40 are BAW resonators and the series resonators of the acoustic wave filter 40 are TCSAW resonators (e.g., any of the TCSAW resonators described herein). In such embodiments, the acoustic wave filter 40 can be a band pass filter. Such a band pass filter can achieve low insertion loss at both a lower band edge and an upper band edge of a passband.

In a band stop filter with a ladder filter topology, such as acoustic wave filter 40, the shunt resonators can have higher resonant frequencies than the series resonators. In certain embodiments, the acoustic wave filter 40 is a band stop filter, the shunt resonators of the acoustic wave filter 40 are TCSAW resonators and the series resonators of the acoustic wave filter 40 are BAW resonators. Such a band stop filter can achieve desirable characteristics in a stop band of the band stop filter.

In some applications of an acoustic wave filter that includes TCSAW series resonators and BAW shunt resonators, such as a transmit filter with a relatively high power handling specification, one or more series resonators close to a transmit port (or the lower frequency series resonators) can be BAW resonators to help with ruggedness.

In certain applications, the ladder filter 40 can be included in a multiplexer in which relatively high gamma for the ladder filter 40 in one or more higher frequency carrier aggregation bands is desired. In such applications, an acoustic filter can include shunt resonators of the shunt type and an acoustic resonator of the second type can be included as a series resonator by which other series resonators of the first type are coupled to a common port of the multiplexer. This can increase gamma of the ladder filter 40 in the one or more higher frequency carrier aggregation bands. For example, in applications where the second input/output port PORT 2 is a common port of a multiplexer, the series resonator RN can be a BAW resonator, other series resonators of the ladder filter 40 can be TCSAW resonators (e.g., any of the TCSAW resonators described herein), and the shunt resonators R1 and RN−1 can be BAW resonators. By having the series resonator RN closest to the common node be a BAW resonator instead of a TCSAW resonator, gamma can be increased for the ladder filter 40 in one or more higher frequency carrier aggregation bands in such applications.

In some applications, the ladder filter 40 can be a transmit filter. In such applications, an acoustic resonator of the second type can be included as a series resonator by which other series resonators of the first type are coupled to a transmit port of the transmit filter. For example, in applications where the second input/output port PORT 2 is a transmit port of a transmit filter, the series resonator RN can be a BAW resonator, other series resonators of the ladder filter 40 can be TCSAW resonators (e.g., any of the TCSAW resonators described herein), and the shunt resonators R1 and RN−1 can be BAW resonators.

In certain applications, the ladder filter 40 can include more than two types of acoustic resonators. In such applications, the majority of the series resonators can be acoustic resonators of the first type (e.g., TCSAW resonators as described herein) and the majority of shunt resonators can be resonators of the second type (e.g., BAW resonators). The ladder filter 40 can include a third type of resonator as a shunt resonator and/or as a series resonator in such applications. The third type of resonator can be a Lamb wave resonator, for example. The acoustic wave filter 40 can include a plurality series resonators including temperature compensated surface acoustic wave resonators and a plurality shunt resonators including a Lamb wave resonator arranged as shunt resonator. The acoustic wave filter 40 can include a plurality series resonators including a Lamb wave resonator and a plurality shunt resonators including bulk acoustic wave resonators arranged as shunt resonators.

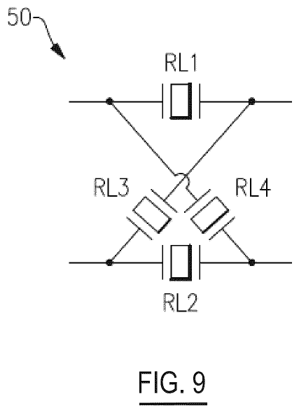

FIG. 9 is a schematic diagram of a lattice filter 50. The lattice filter 50 is an example topology of a band pass filter formed from acoustic wave resonators. The lattice filter 50 can be arranged to filter an RF signal. As illustrated, the lattice filter 50 includes acoustic wave resonators RL1, RL2, RL3, and RL4. The acoustic wave resonators RL1 and RL2 are series resonators. The acoustic wave resonators RL3 and RLA are shunt resonators. The illustrated lattice filter 50 has a balanced input and a balanced output. The lattice filter 50 can be implemented with different type of acoustic resonators in accordance with any suitable principles and advantages disclosed herein. For example, the series resonators RL1 and RL2 can be TCSAW resonators (e.g., any of the TCSAW resonators described herein) and the shunt resonators RL3 and RL4 can be BAW resonators for a band pass filter. In other embodiments, all of the resonators are TSCAW resonators.

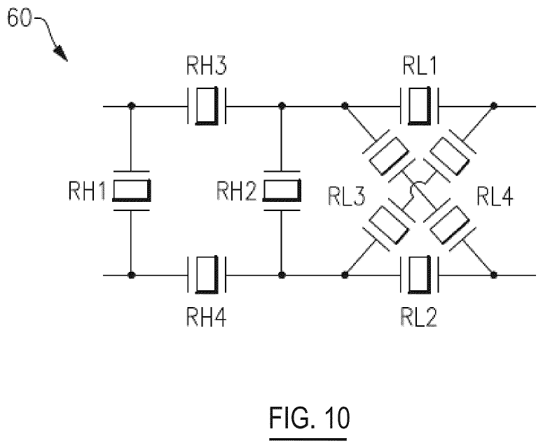

FIG. 10 is a schematic diagram of a hybrid ladder and lattice filter 60. The illustrated hybrid ladder and lattice filter includes series acoustic resonators RL1, RL2, RH3, and RH4 and shunt acoustic resonators RL3, RL4, RH1, and RH2. The hybrid ladder and lattice filter 60 can be implemented with different type of acoustic resonators in accordance with any suitable principles and advantages disclosed herein. For example, the series resonators RL1, RL2, RH3, and RH4 can be TCSAW resonators (e.g., any of the TCSAW resonators described herein) and the shunt resonators RL3, RL4, RH1, and RH2 can be BAW resonators for a band pass filter. In other embodiments, all of the resonators are TCSAW resonators.

### APPLICATIONS

Some of the embodiments described above have provided examples in connection with wireless devices or mobile phones. However, the principles and advantages of the embodiments can be used for any other systems or apparatus that have needs for acoustic wave filters.

Such acoustic wave filters can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An acoustic wave device comprising:
a piezoelectric substrate;
an interdigital transducer electrode disposed on the piezoelectric substrate and configured to excite an acoustic wave having a wavelength of λ; and
a temperature compensating layer disposed on the interdigital transducer electrode and having a dielectric material including a titanium compound.

2. The acoustic wave device of claim 1 wherein the titanium compound is titanium dioxide (TiO₂).

3. The acoustic wave device of claim 1 wherein the dielectric material has a weight proportion of the titanium compound in a range from about 0.1 mass-% to about 10 mass-%.

4. The acoustic wave device of claim 1 wherein the dielectric material has a weight proportion of the titanium compound in a range from about 3 mass-% to about 7 mass-%.

5. The acoustic wave device of claim 1 wherein the dielectric material includes a silicon compound.

6. The acoustic wave device of claim 5 wherein the silicon compound is silicon dioxide (SiO₂).

7. The acoustic wave device of claim 1 wherein the dielectric material is composed such that the acoustic wave device has a temperature coefficient of resonant frequency (TCFs) of at least −32.4 ppm/K.

8. The acoustic wave device of claim 1 wherein the dielectric material is composed such that the acoustic wave device has a temperature coefficient of anti-resonant frequency (TCFp) of at least −19.2 ppm/K.

9. The acoustic wave device of claim 1 wherein the piezoelectric substrate includes lithium tantalate (LiTaO₃).

10. The acoustic wave device of claim 1 wherein the piezoelectric substrate includes lithium niobate (LiNbO₃).

11. The acoustic wave device of claim 1 wherein the acoustic wave device is configured as a surface acoustic wave (SAW) device.

12. A radio frequency module comprising:
an acoustic wave filter including an acoustic wave device and configured to filter a radio frequency signal, the acoustic wave device having a piezoelectric substrate, an interdigital transducer electrode disposed on the piezoelectric substrate and configured to excite an acoustic wave having a wavelength of λ, and a temperature compensating layer disposed on the interdigital transducer electrode and having a dielectric material including a titanium compound; and
a radio frequency circuit element coupled to the acoustic wave filter, the acoustic wave filter and the radio frequency circuit element being enclosed within a common module package.

13. The radio frequency module of claim 12 wherein the radio frequency module is configured as a front end module.

14. The radio frequency module of claim 12 wherein the acoustic wave device is configured as a surface acoustic wave (SAW) device.

15. The radio frequency module of claim 14 wherein the surface acoustic wave (SAW) device is configured as a temperature compensated surface acoustic wave (TCSAW) device.

16. The radio frequency module of claim 14 wherein a filter architecture of the acoustic wave filter is of a Double Mode SAW (DMS) type, a ladder type, a lattice type or a hybrid ladder and lattice type.

17. The radio frequency module of claim 12 wherein the radio frequency circuit element is a radio frequency amplifier arranged to amplify a radio frequency signal.

18. The radio frequency module of claim 12 wherein the radio frequency circuit element is a switch configured to selectively couple the acoustic wave filter to a port of the radio frequency module.

19. A wireless communication device comprising:
an acoustic wave filter including an acoustic wave device and configured to filter a radio frequency signal, the acoustic wave device having a piezoelectric substrate, an interdigital transducer electrode disposed on the piezoelectric substrate and configured to excite an acoustic wave having a wavelength of 2, and a temperature compensating layer disposed on the interdigital transducer electrode and having a dielectric material including a titanium compound;
an antenna operatively coupled to the acoustic wave filter;
a radio frequency amplifier operatively coupled to the acoustic wave filter and configured to amplify the radio frequency signal; and
a transceiver in communication with the radio frequency amplifier.

20. The wireless communication device of claim 19 further comprising a baseband processor in communication with the transceiver.
